(19) United States
(12) Patent Application Publication
(10) Pub. No.: US 2025/0080083 A1
(43) Pub. Date: Mar. 6, 2025

(54) Vibration Device

(71) Applicant: SEIKO EPSON CORPORATION, Tokyo (JP)

(72) Inventors: Makoto FURUHATA, Matsumoto (JP); Kenichi OTO, Sendai (JP)

(21) Appl. No.: 18/820,439

(22) Filed: Aug. 30, 2024

(30) Foreign Application Priority Data
Aug. 31, 2023 (JP) 2023-140817

(51) Int. Cl. H03H 9/205; H03H 9/02; H03H 9/15

(52) U.S. Cl. CPC H03H 9/205; H03H 9/02244; H03H 2009/02165; H03H 2009/02283; H03H 2009/02488; H03H 2009/155

(57) ABSTRACT

A vibration device includes: a vibration substrate that includes a base, a flexural vibration arm joined to the base, and a torsional vibration arm joined to the base; a flexural vibration driver that causes the flexural vibration arm to perform a flexural vibration, the flexural vibration driver being disposed on the vibration substrate; and a torsional vibration driver that causes the torsional vibration arm to perform a torsional vibration, the torsional vibration driver being disposed on the vibration substrate.

The present application is based on, and claims priority from JP Application Serial Number 2023-140817, filed Aug. 31, 2023, the disclosure of which is hereby incorporated by reference herein in its entirety.

### BACKGROUND

### 1. Technical Field

The present disclosure relates to vibration devices.

### 2. Related Art

JP-B-62-46092 discloses a quartz crystal tuning fork as an example of vibration devices, which is designed such that the difference in resonance frequency between the flexural vibration and the torsional vibration falls within 15%. This device can be driven in a coupling mode of the flexural vibration and the torsional vibration, thereby providing good resonance frequency temperature characteristics.

In the above quartz crystal tuning fork, both the flexural vibration and the torsional vibration are performed by a common vibration arm. Thus, the resonance frequencies of the torsional vibration and the flexural vibration cannot be tuned independently of each other. As a result, the difference in the resonance frequency cannot be easily tuned to a predetermined value.

### SUMMARY

The present disclosure is a vibration device which includes: a vibration substrate that includes a base, a flexural vibration arm joined to the base, and a torsional vibration arm joined to the base; a flexural vibration driver that causes the flexural vibration arm to perform a flexural vibration, the flexural vibration driver being disposed on the vibration substrate; and a torsional vibration driver that causes the torsional vibration arm to perform a torsional vibration, the torsional vibration driver being disposed on the vibration substrate.

### BRIEF DESCRIPTION OF THE DRAWINGS

FIG. 1 is a plan view of a MEMS device according to a first embodiment of the present disclosure.

FIG. 2 is a cross-sectional view taken along Line II-II of FIG. 1.

FIG. 3 is a cross-sectional view taken along Line III-III of FIG. 1.

FIG. 4 is a cross-sectional view taken along Line IV-IV of FIG. 1.

FIG. 5 is a plan view of the vibration device.

FIG. 6 is a cross-sectional view of a torsional vibration arm in the vibration device.

FIG. 7 is a cross-sectional view of another torsional vibration arm in the vibration device.

FIG. 8 is a cross-sectional view of the flexural vibration arms in the vibration device.

FIG. 9 illustrates a driven state of the vibration device.

FIG. 10 is a graph showing examples of resonance frequency temperature characteristics.

FIG. 11 is a graph showing other examples of resonance frequency temperature characteristics.

FIG. 12 is a perspective view of a torsional vibration arm disposed in a vibration device according to a second embodiment of the present disclosure.

FIG. 13 is a perspective view of another torsional vibration arm disposed in the vibration device according to the second embodiment.

### DESCRIPTION OF EMBODIMENTS

Some embodiments of a vibration device of the present disclosure will be described below with reference to the accompanying drawings.

### First Embodiment

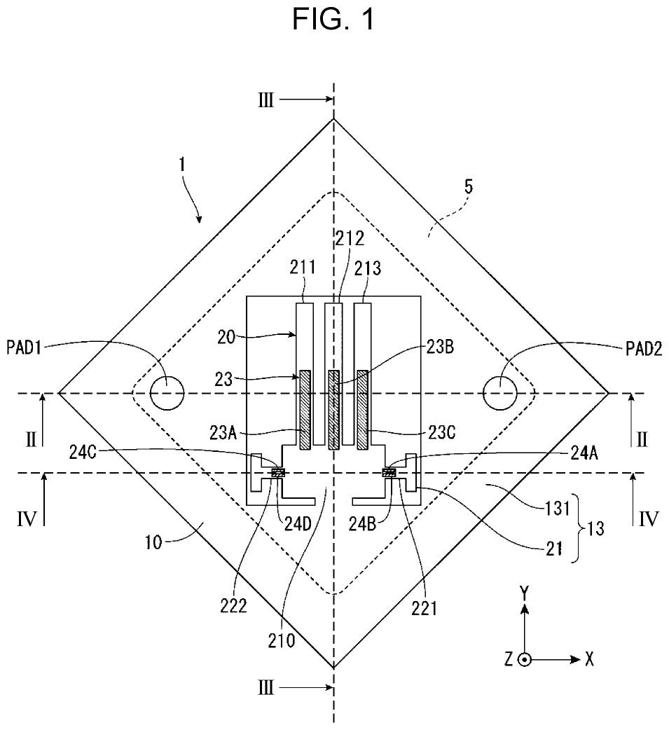

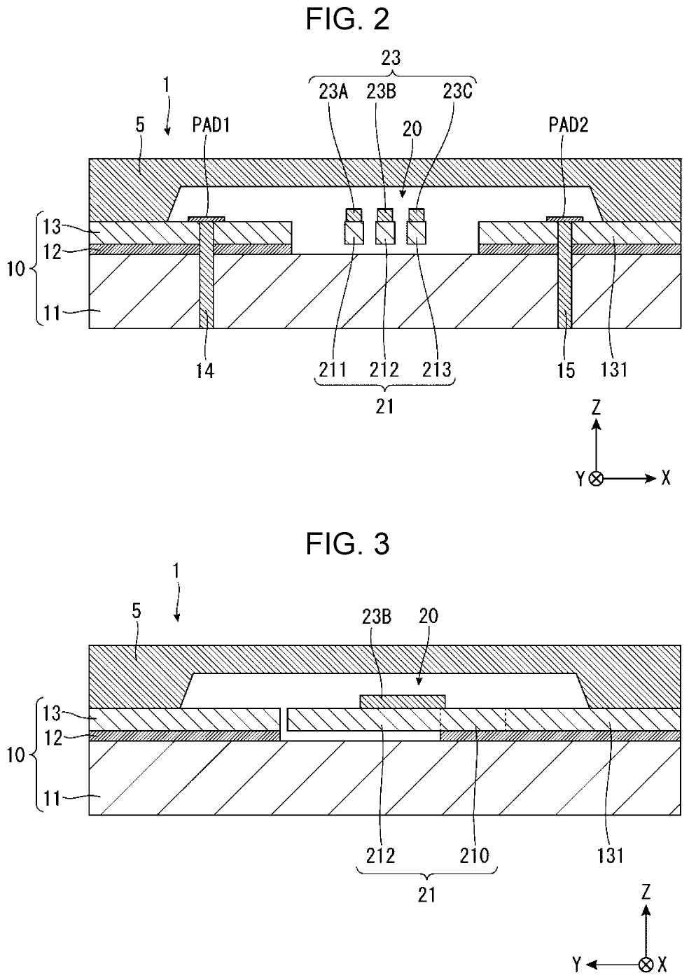

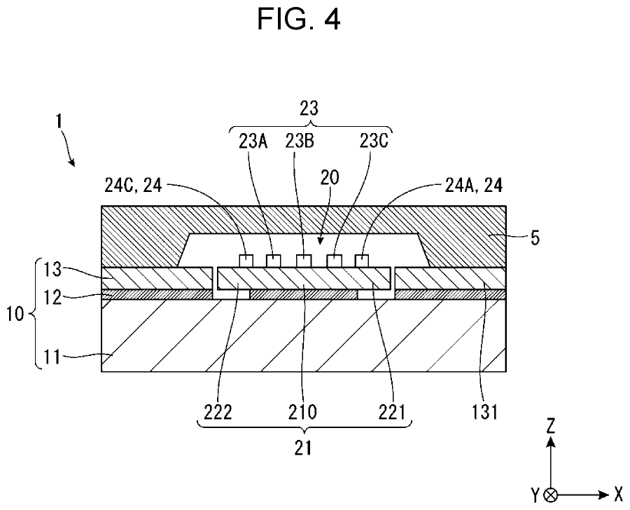

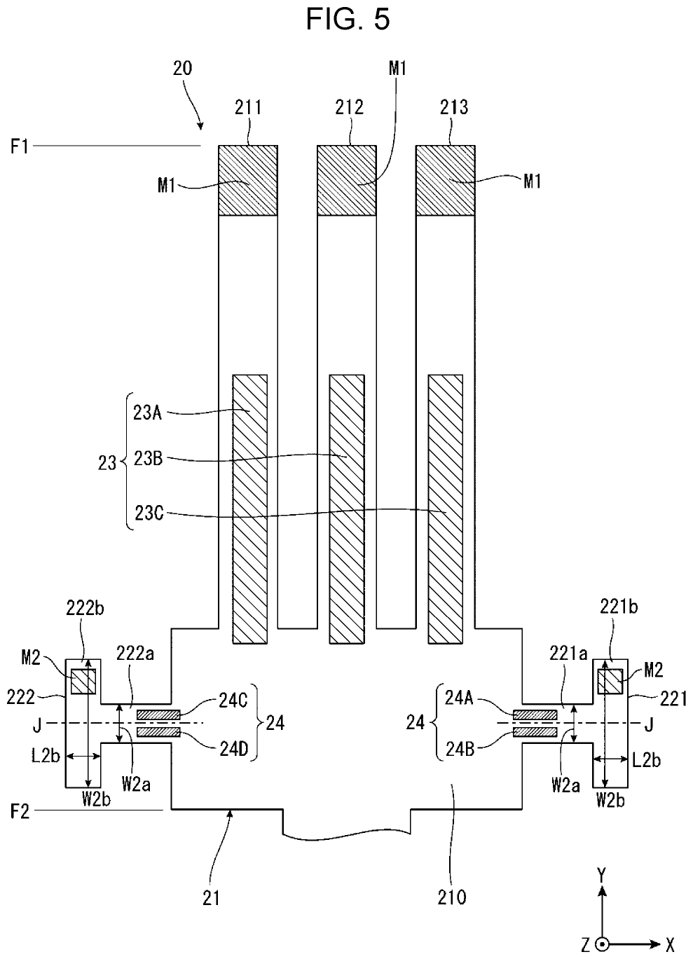

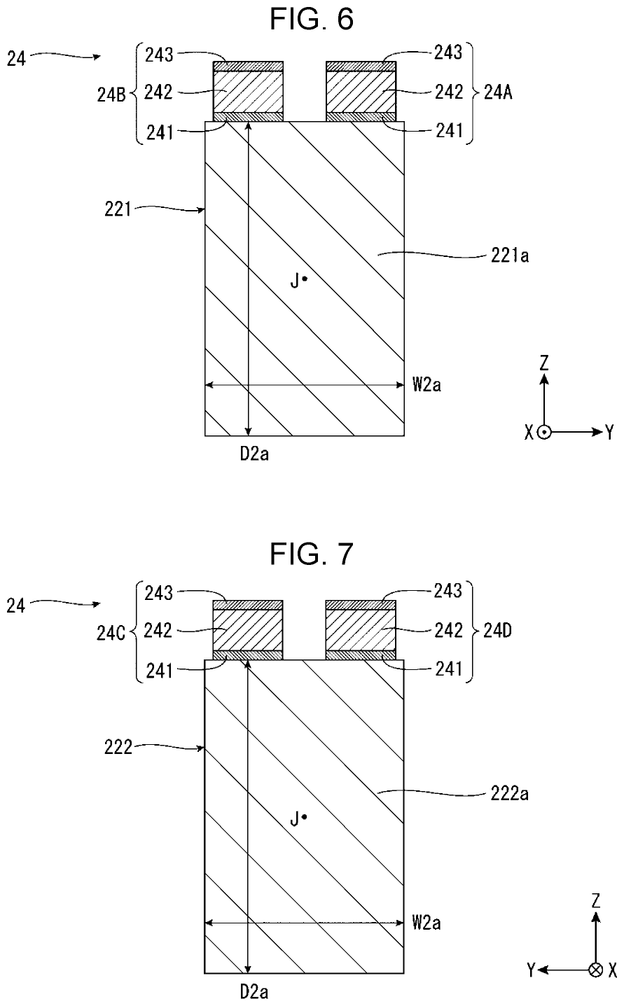

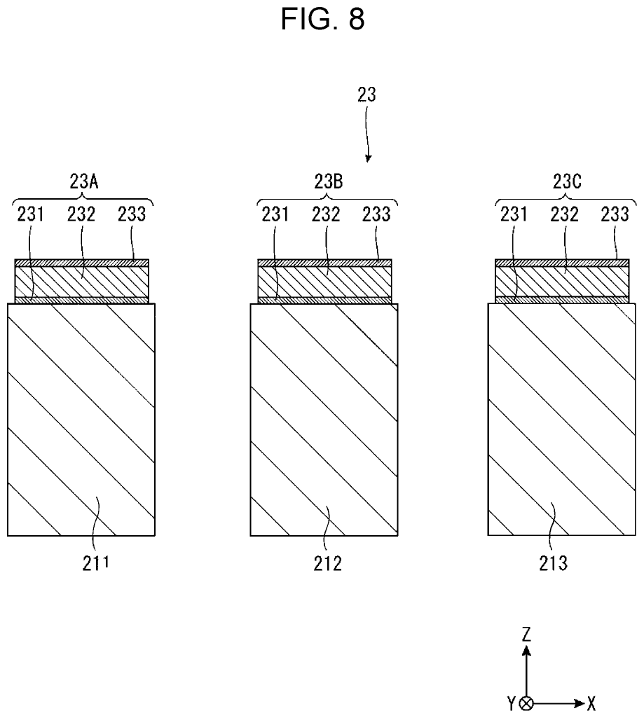

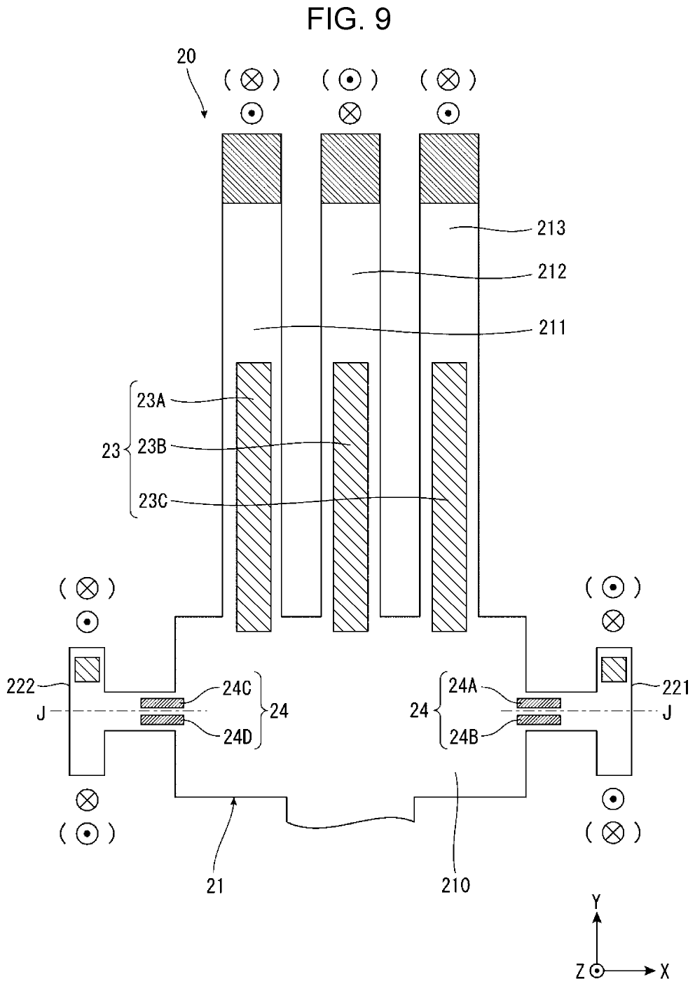

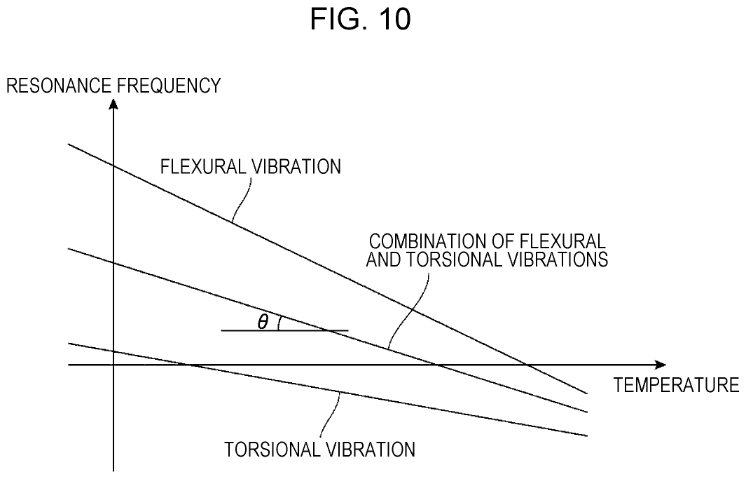

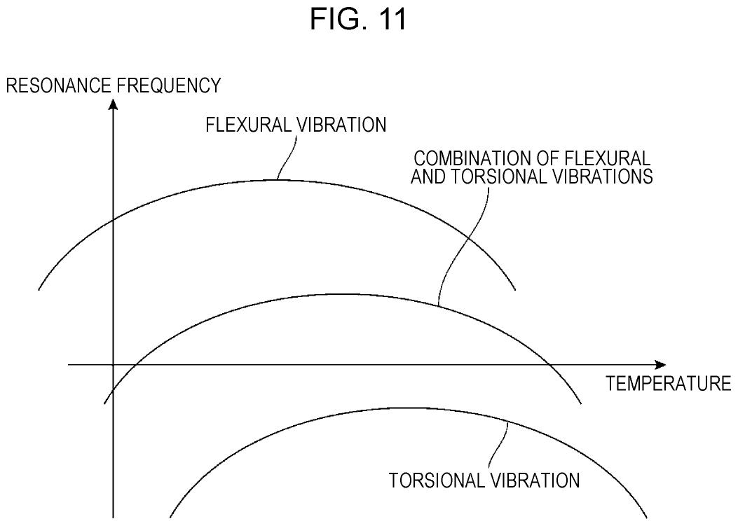

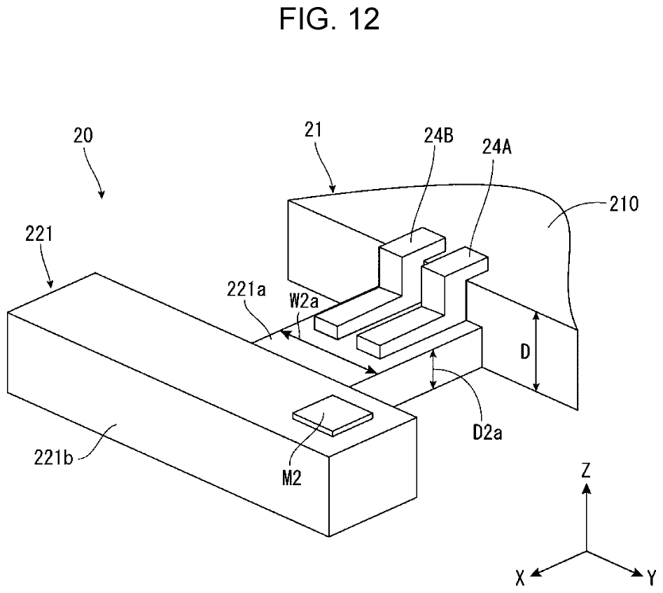

FIG. 1 is a plan view of a MEMS device according to a first embodiment of the present disclosure; FIG. 2 is a cross-sectional view taken along Line II-II of FIG. 1; FIG. 3 is a cross-sectional view taken along Line III-III of FIG. 1; FIG. 4 is a cross-sectional view taken along Line IV-IV of FIG. 1; FIG. 5 is a plan view of the vibration device; FIGS. 6 and 7 are cross-sectional views of the respective torsional vibration arms; FIG. 8 is a cross-sectional view of the flexural vibration arms; FIG. 9 illustrates a driven state of the vibration device; and FIGS. 10 and 11 are graphs showing examples of resonance frequency temperature characteristics.

FIGS. 1 to 9 each illustrate three mutually orthogonal axes, or X, Y, and Z axes, for the sake of the explanation. Hereinafter, the directions denoted by the X-, Y-, and Z-axial arrows in each drawing are defined as the positive (+) directions, whereas the opposite directions are defined as the negative (−) directions. The positive direction along the Z-axis is also defined as the upward direction, whereas the negative direction along the Z-axis is also defined as the downward direction.

As illustrated in FIG. 1, a MEMS device 1 includes: a silicon-on-insulator (SOI) substrate 10 on which a vibration device 20 is formed; and a lid 5 that hermetically seals the vibration device 20. The lid 5, which may be made of monocrystal silicon, has a lower surface with a recess, which is joined to the upper surface of the SOI substrate 10.

As illustrated in FIGS. 2 and 3, the SOI substrate 10 includes a silicon layer 11, a buried oxide (BOX) layer 12, and a surface silicon layer 13, which are stacked on top of one another in this order. Each of the silicon layer 11 and the surface silicon layer 13 may be made of monocrystal silicon, whereas the BOX layer 12 may be made of silicon oxide (SiO₂).

The surface silicon layer 13 includes: a vibration substrate 21; and a frame 131 formed around the vibration substrate 21. As illustrated in FIG. 2, a pair of electrode pads PAD1 and PAD2 are disposed on the upper surface of the frame 131. Immediately below the electrode pad PAD1, a feedthrough electrode 14 is formed so as to penetrate the SOI substrate 10 in a thickness direction thereof, whereas immediately below the electrode pad PAD2, a feedthrough electrode 15 is formed so as to penetrate the SOI substrate 10 in the thickness direction. In addition, the feedthrough electrode 14 is electrically coupled to the electrode pad PAD1, whereas the feedthrough electrode 15 is electrically coupled to the electrode pad PAD2. The electrode pads PAD1 and PAD2 thereby can be electrically coupled to an apparatus disposed outside the MEMS device 1.

The vibration device 20 is provided with the vibration substrate 21 formed in the surface silicon layer 13. Thus, the vibration substrate 21 may be a silicon substrate. In this case, the vibration substrate 21 can be formed easily and precisely by a silicon wafer process. As illustrated in FIGS. 1 to 4, the vibration substrate 21 includes: a base 210 supported on both the silicon layer 11 and the BOX layer 12; three flexural vibration arms, or flexural vibration arms 211, 212, and 213, separated from the BOX layer 12; and two torsional vibration arms, or torsional vibration arms 221 and 222, separated from the BOX layer 12. The vibration substrate 21 may have substantially the same entire thickness as that of the surface silicon layer 13.

As illustrated in FIG. 5, the flexural vibration arms 211, 212, and 213 extend in the +Y direction from the +Y-side of the base 210 while being arranged side by side at equal intervals in the +X direction. In this case, all of the flexural vibration arms 211, 212, and 213 may have substantially the same shape. In addition, each of the flexural vibration arms 211, 212, and 213 is configured to perform a flexural vibration in the ±Z directions.

The upper surfaces of the end portions of the flexural vibration arms 211, 212, and 213 are each provided with a frequency tuning membrane M1 for use in tuning a resonance frequency fr1 of the flexural vibration thereof. By removing a portion of each frequency tuning membrane M1 with laser irradiation, for example, as necessary, the resonance frequency fr1 can be tuned. It should be noted, however, that the configuration of the flexural vibration arms 211, 212, and 213 is not limited; alternatively, no frequency tuning membranes M1 may be disposed thereon.

The torsional vibration arm 221 extends in the +X direction from the +X-side of the base 210, whereas the torsional vibration arm 222 extends in the −X direction from the −X-side of the base 210. In short, the torsional vibration arms 221 and 222 are positioned on the mutually opposite sides of the base 210. With this arrangement, the torsional vibration arms 221 and 222 can be arranged in balance in the vibration device 20. Furthermore, both of the torsional vibration arms 221 and 222 have substantially the same shape. Each of the torsional vibration arms 221 and 222 is configured to perform a torsional vibration around a central axis J thereof. In other words, each of the torsional vibration arms 221 and 222 is configured to perform the torsional vibration around the X-axis.

It should be noted, however, that the arrangement of the torsional vibration arms 221 and 222 is not limited; alternatively, both of the torsional vibration arms 221 and 222 may extend in the +X direction from the +X-side of the base 210 or may extend in the −X direction from the −X-side of the base 210. Moreover, the torsional vibration arms 221 and 222 may extend in the +Y direction from the +Y-side of the base 210 alongside the flexural vibration arms 211, 212, and 213.

The torsional vibration arm 221 includes: an arm portion 221a extending in the +X direction from the +X-side of the base 210; and an weight portion 221b disposed on an outer side of the arm portion 221a. Likewise, the torsional vibration arm 222 includes: an arm portion 222a extending in the −X direction from the −X-side of the base 210; and an weight portion 222b disposed on an end side of the weight portion 222b.

As illustrated in FIGS. 6 and 7, a width W2a, or a length along the Y-axis, of the arm portions 221a and 222a is smaller than a thickness D2a, or a length along the Z-axis, of the arm portions 221a and 222a (W2a<D2a). As a result of this relationship, the cross-section of the arm portions 221a and 222a is formed into a rectangular shape, the longer side of which extends in the +Z direction. Forming the arm portions 221a and 222a in this manner can facilitate both the torsional vibration arms 221 and 222 to smoothly perform the torsional vibration around the X-axis. It should be noted, however, that the shape of the arm portions 221a and 222a is not limited; alternatively, the relationship W2a>D2a may be established as in a second embodiment of the present disclosure, which will be described later. Moreover, the relationship W2a=D2a may also be established.

As illustrated in FIG. 5, a width W2b, or a length along the Y-axis, of the weight portions 221b and 222b is larger than the width W2a of the arm portions 221a and 222a (W2b>W2a). In this configuration, due to the mass effect of the weight portions 221b and 222b, the entire length of the torsional vibration arms 221 and 222 in the +X direction can be made shorter than that in another configuration without the weight portions 221b and 222b, even if the resonance frequencies fr2 (described later) in both the configurations are the same as each other. Thus, this configuration can contribute to the compactness of the vibration device 20. It should be noted, however, that the configuration of the torsional vibration arms 221 and 222 is not limited; alternatively, no weight portions 221b and 222b may be provided therein.

The weight portions 221b and 222b extend in the +Y direction, namely, in the direction identical to the extending direction of the flexural vibration arms 211, 212, and 213. In addition, the width W2b of the weight portions 221b and 222b is larger than a length L2b, or a length along the X-axis, of the weight portions 221b and 222b (W2b>L2b). This configuration enables upsizing of the weight portions 221b and 222b without increasing an entire length of the vibration device 20 in the +Y direction. Thus, the configuration can also contribute to the compactness of the vibration device 20. It should be noted, however, that the configuration of the weight portions 221b and 222b is not limited; alternatively, the relationship (W2b<L2b) may be established.

As illustrated in FIG. 5, the +Y-sides of the weight portions 221b and 222b do not protrude in the +Y direction from outer ends F1 of the flexural vibration arms 211, 212, and 213, whereas the −Y-sides of the weight portions 221b and 222b do not protrude in the −Y direction from base ends F2 of the base 210. This configuration can enable a decrease in the entire length of the vibration device 20 in the +Y direction without increasing the entire length of the vibration device 20 in the +X direction as a result of the addition of the torsional vibration arms 221 and 222. Consequently, the configuration can also contribute to the compactness of the vibration device 20. It should be noted, however, that the configuration of the weight portions 221b and 222b is not limited; alternatively, the +Y-sides of the weight portions 221b and 222b may protrude in the +Y direction from the outer ends F1 of the flexural vibration arms 211, 212, and 213, whereas the −Y-sides of the weight portions 221b and 222b may protrude in the −Y direction from the base side F2 of the base 210.

Each of the weight portions 221b and 222b is provided with a frequency tuning membrane M2 for use in tuning a resonance frequency fr2 of the torsional vibration thereof. By removing a portion of each frequency tuning membrane M2 with laser irradiation, for example, as necessary, the resonance frequency fr2 can be tuned. Each frequency tuning membrane M2 is disposed asymmetrically with respect to the central axis J in plan view as seen from the −Z direction. In this embodiment, the frequency tuning membranes M2 are disposed shifted from the central axis J toward the +Y-sides of the corresponding weight portions 221b. This configuration can help the torsional vibration arms 221 and 222 to smoothly perform the torsional vibrations because the barycenter of each of the torsional vibration arms 221 and 222 is shifted from the central axis J in plan view as seen from the −Z direction. It should be noted, however, that the arrangement of the frequency tuning membranes M2 is not limited.

As illustrated in FIG. 5, the vibration device 20 further includes: a flexural vibration driver 23 that causes the flexural vibration arms 211, 212, and 213 to perform the flexural vibrations in the ±Z directions; and torsional vibration drivers 24 that cause the torsional vibration arms 221 and 222 to perform the torsional vibrations around the X-axis.

As illustrated in FIG. 8, the flexural vibration driver 23 is disposed on the upper surface of the vibration substrate 21. More specifically, the flexural vibration driver 23 includes: a piezoelectric element 23A disposed on the upper surface of the flexural vibration arm 211; a piezoelectric element 23B disposed on the upper surface of the flexural vibration arm 212; and a piezoelectric element 23C disposed on the upper surface of the flexural vibration arm 213. All of the piezoelectric elements 23A, 23B, and 23C may have substantially the same configuration. The piezoelectric element 23A includes: a lower electrode 231 disposed on the upper surface of the flexural vibration arm 211; a piezoelectric layer 232 disposed on the upper surface of the lower electrode 231; and an upper electrode 233 disposed on the upper surface of the piezoelectric layer 232. The piezoelectric element 23B includes: a lower electrode 231 disposed on the upper surface of the flexural vibration arm 212; a piezoelectric layer 232 disposed on the upper surface of the lower electrode 231; and an upper electrode 233 disposed on the upper surface of the piezoelectric layer 232. The piezoelectric element 23C includes: a lower electrode 231 disposed on the upper surface of the flexural vibration arm 213; a piezoelectric layer 232 disposed on the upper surface of the lower electrode 231; and an upper electrode 233 disposed on the upper surface of the piezoelectric layer 232.

As illustrated in FIG. 9, the piezoelectric elements 23A, 23B, and 23C are wired in such a way that the flexural vibration arms 211, 212, and 213 disposed adjacent to one another can perform the flexural vibrations in mutually opposite phases. In other words, the piezoelectric elements 23A, 23B, and 23C are wired in such a way that a first state and a second state alternatively and repeatedly appear. In the first state, both the flexural vibration arms 211 and 213 are bent upwardly but the flexural vibration arm 212 is bent downwardly; in the second state, both the flexural vibration arms 211 and 213 are bent downwardly but the flexural vibration arm 212 is bent upwardly. More specifically, the lower electrodes 231 of the piezoelectric elements 23A and 23C and the upper electrode 233 of the piezoelectric element 23B are electrically coupled to the electrode pad PAD1 via respective wire lines (not illustrated). The upper electrodes 233 of the piezoelectric elements 23A and 23C and the lower electrode 231 of the piezoelectric element 23B are electrically coupled to the electrode pad PAD2 via respective wire lines (not illustrated). When the flexural vibration arms 211, 212, and 213 disposed adjacent to one another perform the flexural vibrations in mutually opposite phases, as described above, the vibrations of the flexural vibration arms 211, 212, and 213 cancel out to successively effectively suppress vibrations of the vibration device 20 from being transmitted to the outside.

As illustrated in FIG. 5, each torsional vibration driver 24 is disposed on the upper surface of the vibration substrate 21. More specifically, a first one of the torsional vibration drivers 24 includes a pair of piezoelectric elements 24A and 24B disposed on the upper surface of the arm portion 221a of the torsional vibration arm 221, whereas a second one of the torsional vibration drivers 24 includes a pair of piezoelectric elements 24C and 24D disposed on the upper surface of the arm portion 222a of the torsional vibration arm 222. In this case, the pair of piezoelectric elements 24A and 24B are arranged with the central axis J of the arm portion 221a therebetween in plan view as seen from the −Z direction. Further, the piezoelectric element 24A is disposed on the +Y-side with respect to the central axis J, whereas the piezoelectric element 24B is disposed on the −Y-side with respect to the central axis J. This arrangement can help the torsional vibration arm 221 to smoothly perform the torsional vibration. Likewise, the pair of piezoelectric elements 24C and 24D are arranged with the central axis J of the arm portion 222a therebetween in plan view as seen from the −Z direction. Further, the piezoelectric element 24C is disposed on the +Y-side with respect to the central axis J, whereas the piezoelectric element 24D is disposed on the −Y-side with respect to the central axis J. This arrangement can help the torsional vibration arm 222 to smoothly perform the torsional vibration.

As illustrated in FIGS. 6 and 7, all of the piezoelectric elements 24A, 24B, 24C, and 24D may have substantially the same configuration. More specifically, each of the piezoelectric elements 24A and 24B includes: a lower electrode 241 disposed on the upper surface of the arm portion 221a; a piezoelectric layer 242 disposed on the upper surface of the lower electrode 241; and an upper electrode 243 disposed on the upper surface of the piezoelectric layer 242. Likewise, each of the piezoelectric elements 24C and 24D includes: a lower electrode 241 disposed on the upper surface of the arm portion 222a; a piezoelectric layer 242 disposed on the upper surface of the lower electrode 241; and an upper electrode 243 disposed on the upper surface of the piezoelectric layer 242.

As illustrated in FIG. 9, the piezoelectric elements 24A, 24B, 24C, and 24D are wired in such a way that the torsional vibration arms 221 and 222 can perform the torsional vibrations in mutually opposite phases. In other words, the piezoelectric elements 24A, 24B, 24C, and 24D are wired in such a way that a third state and a fourth state repeatedly and alternately appear. In the third state, the torsional vibration arms 221 and 222 are twisted clockwise and counterclockwise, respectively, in plan view as seen from the −X direction; in the fourth state, the torsional vibration arms 221 and 222 are twisted counterclockwise and clockwise, respectively, in plan view as seen from the +X direction. More specifically, the upper electrodes 243 of the piezoelectric elements 24A and 24D and the lower electrodes 241 of the piezoelectric elements 24B and 24C are electrically coupled to the electrode pad PAD1 via respective wire lines (not illustrated). Likewise, the lower electrodes 241 of the piezoelectric elements 24A and 24D and the upper electrodes 243 of the piezoelectric elements 24B and 24C are electrically coupled to the electrode pad PAD2 via respective wire lines (not illustrated). When the torsional vibration arms 221 and 222 perform the torsional vibrations in mutually opposite phases, as described above, the vibrations of the torsional vibration arms 221 and 222 cancel out to successively effectively suppress vibrations of the vibration device 20 from being transmitted to the outside.

As described above, the piezoelectric elements 23A, 23B, and 23C disposed in the flexural vibration driver 23 and the piezoelectric elements 24A, 24B, 24C, and 24D disposed in the torsional vibration drivers 24 are electrically coupled to both the electrode pads PAD1 and PAD2. As a result, the flexural vibration driver 23 is electrically coupled to the torsional vibration driver 24. In this case, the materials of sections in each of the piezoelectric elements 23A, 23B, 23C, 24A, 24B, 24C, and 24D are not limited; for example, the piezoelectric layers 232 and 242 are made of aluminum nitride (AlN), and the lower electrodes 231 and 241 and the upper electrodes 233 and 243 are made of titanium nitride (TiN).

When the resonance frequency of the flexural vibration performed by the flexural vibration arms 211, 212, and 213 is denoted by fr1 and the resonance frequency of the torsional vibration performed by the torsional vibration arms 221 and 222 is denoted by fr2, the resonance frequencies fr1 and fr2 may be tuned in such a way that the difference Δfr (=|fr1−fr2|) between the resonance frequencies fr1 and fr2 becomes equal to or less than 1% of the resonance frequency fr1. More specifically, the resonance frequency fr1 may be, first, tuned to a desired one such as 32 kHz, and then the resonance frequency fr2 may be tuned in such a way that the difference Δfr becomes equal to or less than 1% of the resonance frequency fr1. As a result, the flexural vibration arms 211, 212, and 213 perform the flexural vibrations simultaneously with the torsional vibrations of the torsional vibration arms 221 and 222. In this way, the torsional vibrations can be coupled to the flexural vibrations.

Instead of tuning the difference Δfr to equal to or less than 1% of the resonance frequency fr1, the difference Δfr may also be set to equal to or less than 0.1%, equal to or less than 0.01%, or equal to 0%. By tuning the resonance frequencies fr1 and fr2 in this manner, the flexural vibration arms 211, 212, and 213 can reliably perform the flexural vibrations simultaneously with the torsional vibrations of the torsional vibration arms 221 and 222. In this embodiment, the flexural vibration refers to a fundamental wave (fundamental wave mode) rather than a higher harmonic wave (higher-order mode). Likewise, the torsional vibration refers to a fundamental wave (fundamental wave mode) rather than a higher harmonic wave (higher-order mode).

The torsional vibrations and the flexural vibrations can be coupled together, as described above, thereby providing the vibration device 20 with good resonance frequency temperature characteristics. Referring to the graph in FIG. 10, for example, the resonance frequency of a vibration device 20 in which torsional vibrations and flexural vibrations are coupled together is less dependent on temperature change than that of a vibration device 20 that performs flexural vibrations alone. In short, the vibration device 20 in which the torsional vibrations and the flexural vibrations are coupled together exhibits superior resonance frequency temperature characteristics. In the example of FIG. 10, each vibration device 20 has linear resonance frequency temperature characteristics. However, if a vibration substrate 21 includes an ion-doped surface silicon layer 13, for example, the vibration device 20 may have quadratic resonance frequency temperature characteristics, as demonstrated by the graph of FIG. 11. Even in this case, the resonance frequency of a vibration device 20 in which torsional vibrations and flexural vibrations are coupled together is less dependent on temperature change than that of a vibration device 20 that performs flexural vibrations alone. In short, the vibration device 20 in which the torsional vibrations and the flexural vibrations are coupled together also exhibits superior resonance frequency temperature characteristics.

The flexural vibration arms 211, 212, and 213 and the torsional vibration arms 221 and 222 are disposed in the vibration device 20 independently of one another, thereby enabling independent tuning of the resonance frequencies fr1 and fr2. Consequently, it is possible to easily tune the resonance frequency fr1 to a desired one and also tune the difference Δfr to equal to or less than a predetermined value.

The resonance frequency fr2 tends to be higher than the resonance frequency fr1. For example, if a MEMS device 1 includes crystal resonators, when the resonance frequency fr1 is tuned to 32 kHz, the resonance frequency fr2 cannot be lowered to about less than 100 kHz due to limitations of processing precision of wet etching. However, if the MEMS device 1 includes the vibration device 20 formed of a silicon substrate (surface silicon layer 13) which can be processed finely and precisely by a silicon wafer process such as dry etching as in this embodiment, the arm portion 221a of the torsional vibration arm 221 and the arm portion 222a of the torsional vibration arm 222 can be etched until the width W2a becomes small. As a result, the resonance frequency fr2 can be easily lowered so as to substantially equate with the resonance frequency fr1.

When a drive voltage is applied between the electrode pads PAD1 and PAD2 in the vibration device 20 configured above, as illustrated in FIG. 9, the piezoelectric element 23B and both the piezoelectric element 23A and 23C expand and contract in mutually opposite phases. In response, the flexural vibration arms 211, 212, and 213 disposed adjacent to one another perform the flexural vibrations in the ±Z directions in mutually opposite phases. Furthermore, the pair of piezoelectric elements 24A and 24D and the pair of piezoelectric elements 24B and 24C expand and contract in mutually opposite phases. In response, the torsional vibration arms 221 and 222 perform the torsional vibrations around the X-axis in opposite phase. In this way, the torsional vibrations of the torsional vibration arms 221 and 222 and the flexural vibrations of the flexural vibration arms 211, 212, and 213 can be coupled together to produce the above effect. The flexural vibrations of the flexural vibration arms 211, 212, and 213 are greatly excited at the resonance frequency fr1, so that the impedance is minimized. When the MEMS device 1 is electrically coupled to an oscillation circuit, this oscillation circuit can oscillate at the frequency determined by the resonance frequency fr1.

A MEMS device 1 with a vibration device 20 has been described. As described above, the vibration device 20 includes a vibration substrate 21 that includes: a base 210; flexural vibration arms 211, 212, and 213 joined to the base 210; and torsional vibration arms 221 and 222 joined to the base 210. The vibration device 20 further includes: a flexural vibration driver 23 that causes the flexural vibration arms 211, 212, and 213 to perform flexural vibrations, the flexural vibration driver 23 being disposed on the vibration substrate 21; and a torsional vibration driver 24 that causes the torsional vibration arms 221 and 222 to perform torsional vibrations, the torsional vibration driver 24 being disposed on the vibration substrate 21. The flexural vibration arms 211, 212, and 213 that perform the flexural vibrations and the torsional vibration arms 221 and 222 that perform the torsional vibrations are disposed in the vibration substrate 21 independently of one another, thereby enabling independent tuning of a resonance frequency fr1 of the flexural vibrations and a resonance frequency fr2 of the torsional vibrations. Consequently, it is possible to easily tune a difference Δfr between the resonance frequencies fr1 and fr2 to a predetermined value with the resonance frequency fr1 kept in a desired frequency band.

As described above, the torsional vibration arm 221 may include an arm portion 221a extending from the base 210, and the torsional vibration arm 222 includes an arm portion 222a extending from the base 210. A width W2a of the arm portions 221a and 222a may be smaller than a thickness D2a of the arm portions 221a and 222a. This configuration may be able to help the torsional vibration arms 221 and 222 to smoothly perform the torsional vibrations.

As described above, the torsional vibration arm 221 may further include an weight portion 221b disposed on an outer side of the arm portion 221a, and the torsional vibration arm 222 may further include an weight portion 222b disposed on an outer side of the arm portion 222a. A width W2b of the weight portions 221b and 222b may be larger than the width W2a of the arm portions 221a and 222a. With this configuration, due to the mass effect of the weight portions 221b and 222b, the entire length of the torsional vibration arms 221 and 222 may be able to be made shorter than that of a configuration without the weight portions 221b and 222b, even if the resonance frequencies fr2 (described later) in both the configurations are the same as each other. Thus, the configuration may be able to contribute to the compactness of the vibration device 20.

As described above, the weight portions 221b and 222b may extend in a direction identical to an extending direction of the flexural vibration arms 211, 212, and 213. This configuration may enable upsizing of the weight portions 221b and 222b without increasing an entire length of the vibration device 20 in the +Y direction. Thus, this configuration may also be able to contribute to the compactness of the vibration device 20.

As described above, the vibration substrate 21 may further include a pair of torsional vibration arms 221 and 222 positioned on mutually opposite sides of the base 210. In addition, the torsional vibration driver 24 may cause the torsional vibration arms 221 and 222 to perform the torsional vibrations in mutually opposite phases. With this configuration, vibrations of the torsional vibration arms 221 and 222 may cancel out to successfully effectively suppress vibrations of the vibration device 20 from being transmitted to the outside.

As described above, the vibration substrate 21 may include three flexural vibration arms 211, 212, and 213 arranged side by side in a direction orthogonal to an extending direction thereof, or in an X-axis. In addition, the flexural vibration driver 23 may cause the flexural vibration arm 212 positioned at a center and the flexural vibration arms 211 and 213 positioned on both sides to perform the flexural vibrations in mutually opposite phases. With this configuration, vibrations of the flexural vibration arms 211, 212, and 213 may cancel out to successfully effectively suppress vibrations of the vibration device 20 from being transmitted to the outside.

As described above, the vibration substrate 21 may be formed of a surface silicon layer 13, which is a silicon substrate. The vibration substrate 21 configured above may be able to be formed by a silicon wafer process. Thus, the vibration substrate 21 may be able to be processed easily and precisely.

### Second Embodiment

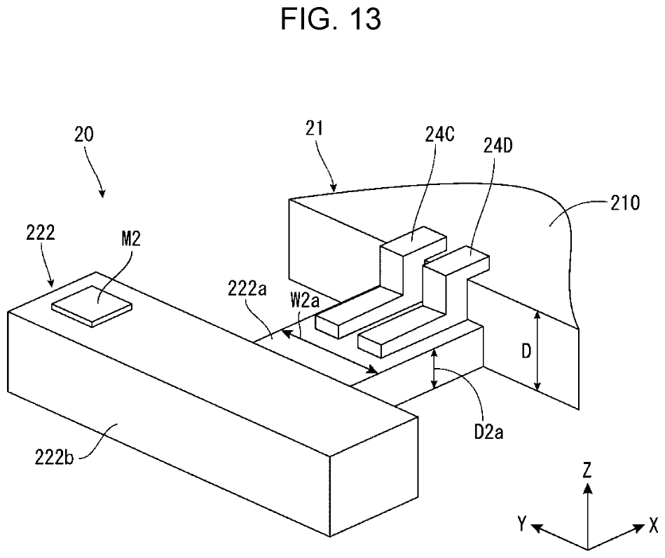

FIG. 12 is a perspective view of a torsional vibration arm disposed in a vibration device according to a second embodiment of the present disclosure; FIG. 13 is a perspective view of another torsional vibration arm disposed in the vibration device according to the second embodiment.

Except for a shape of torsional vibration arms 221 and 222, this embodiment is substantially the same as the foregoing first embodiment. Hereinafter, differences in features between this embodiment and the first embodiment will be described, and the identical features will not be described. In FIGS. 12 and 13, components in this embodiment which are identical to those in the first embodiment are given the same characters.

In a vibration device 20 according to this embodiment, as illustrated in FIGS. 12 and 13, a width W2a of an arm portion 221a in the torsional vibration arm 221 and an arm portion 222a in the torsional vibration arm 222 is larger than a thickness D2a of the arm portions 221a and 222a (W2a>D2a). In this case, the cross-section of each of the arm portions 221a and 222a is formed into a rectangular shape, the long side of which extends in the +Y direction. This configuration can help both the torsional vibration arms 221 and 222 to smoothly perform torsional vibrations.

In this embodiment, the thickness D2a of the arm portions 221a and 222a is smaller than a thickness D of a vibration substrate 21, namely, the thickness of a surface silicon layer 13. In this case, the stiffness of the arm portions 221a and 222a may decrease. As a result, a resonance frequency fr2 can be easily lowered to the level of a resonance frequency fr1. The arm portions 221a and 222a configured above are formed by making the vibration substrate 21 thinner from the top. In this way, the arm portions 221a and 222a can be easily formed. It should be noted, however, that a process of forming the arm portions 221a and 222a is not limited; alternatively, the arm portions 221a and 222a may be formed by making the vibration substrate 21 thinner from the bottom.

According to this embodiment, as described above, a vibration device 20 includes a base 210; a torsional vibration arm 221 that has an arm portion 221a extending from the base 210; and a torsional vibration arm 222 that has an arm portion 222a extending from the base 210. In this case, a width W2a of the arm portions 221a and 222a is larger than a thickness D2a of the arm portions 221a and 222a. This configuration can help both the torsional vibration arms 221 and 222 to smoothly perform torsional vibrations.

The second embodiment described above can produce substantially the same effects as the foregoing first embodiment.

Some embodiments of the vibration device of the present disclosure have been described with reference to the accompanying drawings; however, the present disclosure is not limited to such embodiments. Some of the components described above may be replaced with ones having equivalent functions. Furthermore, any other components may be added to the present disclosure. Moreover, the present disclosure may be implemented by combining two or more of the components in the first and second embodiments.

What is claimed is:

1. A vibration device comprising:
a vibration substrate that includes a base, a flexural vibration arm joined to the base, and a torsional vibration arm joined to the base;
a flexural vibration driver that causes the flexural vibration arm to perform a flexural vibration, the flexural vibration driver being disposed on the vibration substrate; and
a torsional vibration driver that causes the torsional vibration arm to perform a torsional vibration, the torsional vibration driver being disposed on the vibration substrate.

2. The vibration device according to claim 1, wherein
the torsional vibration arm includes an arm portion extending from the base, and
a width of the arm portion is smaller than a thickness of the arm portion.

3. The vibration device according to claim 1, wherein
the torsional vibration arm includes an arm portion extending from the base, and
a width of the arm portion is larger than a thickness of the arm portion.

4. The vibration device according to claim 2, wherein
the torsional vibration arm further includes a weight portion disposed on an end side of the arm portion, and
a width of the weight portion is larger than the width of the arm portion.

5. The vibration device according to claim 4, wherein
the weight portion extends in a direction identical to an extending direction of the flexural vibration arm.

6. The vibration device according to claim 1, wherein
the vibration substrate includes a pair of torsional vibration arms positioned on mutually opposite sides of the base, and
the torsional vibration driver causes the pair of torsional vibration arms to perform torsional vibrations in mutually opposite phases.

7. The vibration device according to claim 1, wherein
the vibration substrate includes three flexural vibration arms arranged side by side in a direction orthogonal to an extending direction thereof, and
the flexural vibration driver causes, out of the flexural vibration arms, a flexural vibration arm positioned at a center and a pair of flexural vibration arms positioned on both sides to perform flexural vibrations in mutually opposite phases.

8. The vibration device according to claim 1, wherein
the vibration substrate is a silicon substrate.

9. A vibration device comprising:
a vibration substrate that includes a base, a flexural vibration arm joined to the base, and a pair of torsional vibration arms positioned on mutually opposite sides of the base;
a flexural vibration driver that causes the flexural vibration arm to perform a flexural vibration, the flexural vibration driver being disposed on the vibration substrate; and
a torsional vibration driver that causes the torsional vibration arms to perform torsional vibrations, the torsional vibration driver being disposed on the vibration substrate.

10. The vibration device according to claim 9, wherein
the vibration substrate includes three flexural vibration arms arranged side by side in a direction orthogonal to an extending direction thereof, and
the flexural vibration driver causes, out of the flexural vibration arms, a flexural vibration arm positioned at a center and a pair of flexural vibration arms positioned on both sides to perform flexural vibrations in mutually opposite phases.

11. The vibration device according to claim 9, wherein
the vibration substrate is a silicon substrate.
